(19) United States
(12) Patent Application Publication
(10) Pub. No.: US 2008/0217756 A1
(43) Pub. Date: Sep. 11, 2008

(54) POWER SEMICONDUCTOR ARRANGEMENT AND METHOD FOR PRODUCING IT

(75) Inventors: Richard Boettcher, Warstein (DE); Christian Robohm, Lipstadt (DE); Oliver Schilling, Warstein (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Neubiberg (DE)

(21) Appl. No.: 12/043,620

(22) Filed: Mar. 6, 2008

(30) Foreign Application Priority Data
Mar. 6, 2007 (DE) 10 2007 010 883.6

(51) Int. Cl. H01L 23/52; H01L 21/00

(52) U.S. Cl. 257/691; 438/122; 257/E23.141; 257/E21.001

(57) ABSTRACT

Power semiconductor arrangement and method for producing it. One embodiment provides a power semiconductor module. The power semiconductor module has a baseplate with an electrically conductive structure, a housing and a connection element. The connection element is led out from the housing generally perpendicular to the baseplate and is fixed to the housing, has a first connection configured for making contact with the electrically conductive structure, and has a second connection for making electrical contact with a circuit carrier.

### CROSS-REFERENCE TO RELATED APPLICATIONS

This Utility patent application claims priority to German Patent Application No. DE 10 2007 010 883.6-33 filed on Mar. 6, 2007, which is incorporated herein by reference.

### BACKGROUND

Power semiconductor modules usually have at least one insulating baseplate, wherein an electrically conductive structure is mounted on the baseplate and at least one power semiconductor component is in turn arranged on the structure. Baseplates of this type are also referred to as substrate or printed circuit board. The electrically conductive structures on the insulating baseplate serve for making contact with the power semiconductor components. By way of example, diodes, transistors, insulated gate bipolar transistors (IGBT) or thyristors are used as power semiconductor components.

The baseplate, on the side remote from the power semiconductor components, is usually attached to a heat sink for dissipating the heat occurring at the power semiconductor components. The power semiconductor components can be electrically connected to an external circuit carrier, such as, for example, a printed circuit card carrying a driver circuit, with the aid of contact-connecting pins that run for example perpendicular to the baseplate and are electrically connected thereto. Reliable contact particularly at high currents is needed for fault-free operation of a power semiconductor module.

For these and other reasons, there is a need for the present invention.

### SUMMARY

One embodiment provides a power semiconductor arrangement including a power semiconductor module, wherein the power semiconductor module includes a baseplate with an electrically conductive structure, a housing and a connection element. The connection element is led out from the housing generally perpendicular to the baseplate and is fixed to the housing, including a first connection configured for making contact with the electrically conductive structure and a second connection configured for making electrical contact with the circuit carrier.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 is a cross sectional view of an arrangement having a circuit carrier and a power semiconductor module with a connection element.

FIG. 2 is a cross sectional view of a further arrangement having a circuit carrier and a power semiconductor module with a connection element.

FIG. 3 is a cross sectional view of a combination of the arrangements of FIG. 1 and FIG. 2.

FIG. 4 is a cross sectional view of a power semiconductor component with a housing and a connection element injected into the housing.

FIG. 5 is a plan view of the connection element of FIG. 4 in the mounted state.

FIG. 6 is a cross sectional view of a power semiconductor component with a housing, a baseplate and a connection element inserted into the housing in the direction of the baseplate.

FIG. 7 is a plan view of the connection element of FIG. 6 in the mounted state.

FIG. 8 is a cross sectional view of the housing and the connection element of FIG. 6 rotated by 90 degrees.

FIG. 9 is a cross sectional view of a power semiconductor component with a housing, a baseplate and a connection element inserted into the housing away from the baseplate.

FIG. 10 is a plan view of the connection element of FIG. 9 in the mounted state.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

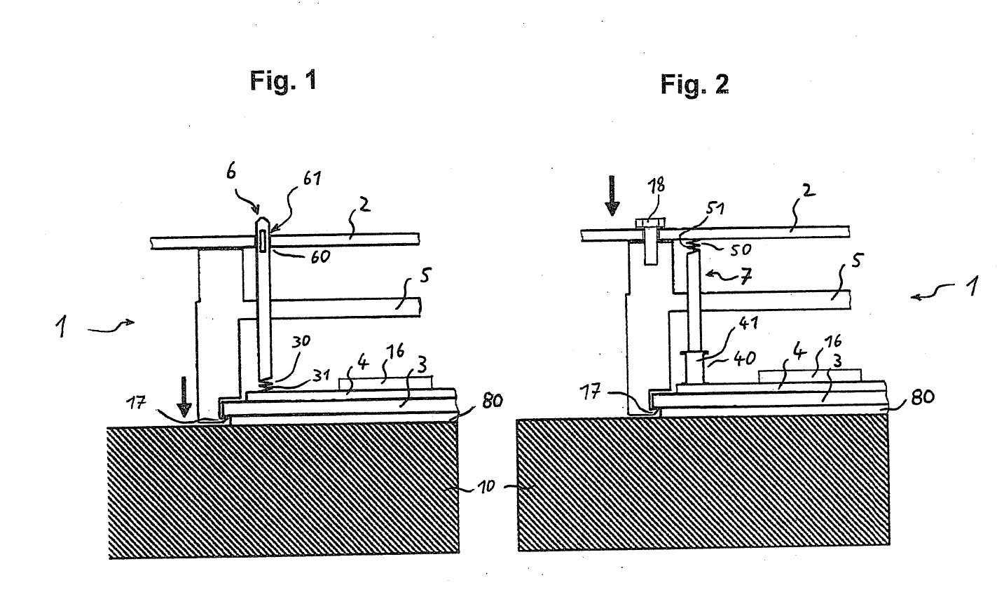

FIG. 1 illustrates one embodiment of an arrangement including a power semiconductor module 1 having a baseplate 3, a housing 5 and a connection element 6. The baseplate 3 formed in insulating fashion—also referred to as a substrate—may be composed of a ceramic material such as HPS Al₂O₃, AlN or Si₃N₄. An electrically conductive structure 4 such as a structured metallic layer, for instance, is situated on the baseplate 3. Power semiconductor components 16 are arranged on the electrically conductive structure 4 and are contact-connected using the structure 4. A further layer 80 having good thermal conductivity may be situated on that side of the baseplate 3 which is remote from the structure 4 described above. The layer 80 may likewise be structured or else unstructured and may be formed as a metallic layer like the electrically conductive structure 4. The appropriate materials for the abovementioned layers 4, 80 include copper and aluminum but also other metals and alloys. The baseplate 3 and the coatings on both sides of the baseplate 3 can form a DCB (Direct Copper Bonding) substrate, wherein the baseplate 3 is composed of a ceramic material and the layers 4, 80 on both sides of the baseplate 3 are composed of copper.

In one embodiment, however, AMB substrates (AMB=Active Metal Brazing), DAB substrates (DAB=Direct Aluminum Bonding) or customary brazed substrates (regular brazing type substrates) may also be used as circuit carrier. The baseplate 3 and the layers 4, 80 applied on the baseplate 3 can additionally be coated on the entire surface of the baseplate 3 or selectively with further materials. Thus, in the embodiment of an aluminum metallization, for example, this coating may contain the following substances or compounds: Ni/Au, Ni/Ag, Cu, Cu/Ni/Au, Cu/Ag, Ni/Pd, Ni/Pd/Ag, Ti/Ni/Au, Ti/Ni/Ag, Cr/Ni/Au and Cr/Ni/Ag. In the embodiment of a copper metallization, for example, the materials Au, Ag, Pd, Pt, W, Mo, Mn or combinations thereof are used. The baseplate 3 is connected via the layer remote from the electrically conductive structure 4, that is to say via the layer 80, to a heat sink 10 for dissipating heat from the power semiconductor module.

A connection element 6 is arranged on the electrically conductive structure 4, the connection element being led out from the housing 5 generally perpendicular to the baseplate 3. The connection element 6 may be produced from copper, brass, steel (in one embodiment spring steel) or comparable alloys. Other conductive materials are likewise possible. The connection element 6 produces an electrical connection between the structure 4 and a circuit carrier 2 situated above the housing 5 on the power semiconductor module 1. The circuit carrier 2 may include a driver circuit, for example, which is situated on a printed circuit card.

The connection element 6 is fixed to the housing 5 between a first connection of the connection element 6, which is provided for making contact with the electrically conductive structure 4, and a second connection of the connection element 6, which is provided for making contact with the circuit carrier 2. The firm fixing is such that a captively handleable unit including connection element 6 and housing 5 is created. The housing 5 is electrically insulating and may include glass-fiber-reinforced plastic, for example. The connection element 6 is therefore connected cohesively to the housing 5. Connection between the connection element 6 and the housing 5 is effected, for example, by the connection element 6 being injected into the housing. The housing 5 in turn is fixedly connected to the baseplate 3, which can be effected for example using a screw connection, an adhesive bonding or, as illustrated, using latching hooks 17.

In one embodiment, the first connection of the connection element 6 is in a form of a pressure contact 30 with a spring 31. On account of the firm fixing of the connection element to the housing 5 and the fixed connection between the housing 5 and the baseplate 3, during the production of the connection between the housing 5 and baseplate 3 (see the arrow in FIG. 1) an electrical connection between the connection element 6 and the structure 4 can simultaneously be produced via the pressure contact 30.

By virtue of the firm fixing of the connection element 6 to the housing 5, for example in a premounting process, a separate process of contact-connecting the connection element 6 to the structure 4 can thus be dispensed with and instead be performed in a process together with fitting the housing 5 on the baseplate 3. Furthermore, no soldering connections are required between connection element 6 and structure 4, on the one hand, and connection element 6 and circuit carrier 2, on the other hand. Instead of a soldering connection, the first connection of the connection element 6 is formed as a pressure contact 30, as mentioned. In one embodiment, however, a plug contact or a screw contact can be used. In the present embodiment, the second connection of the connection element 6 is in the form of a plug contact 60, but can be a pressure contact or a screw contact. In this embodiment, the connection element 6 is led through an opening 61 in the circuit carrier 2. The firm fixing of the connection element 6 to the housing 5 makes it possible for different forces at the first connection and at the second connection of the connection element 6 to be introduced into the connection element 6 and be forwarded to the housing 5. The connection element 6 has for example an elongated, cylindrical form resulting in an axial introduction of the counterforce of the pressure contact 30 into the connection element 6 and complete forwarding of the force to the housing 5.

In addition to serving for electrical connection between the connection element 6 and circuit carrier 2, the plug contact 60 serves for positioning the circuit carrier 2 with respect to the housing 5. Apart from the plug contact 60, a more extensive connection between the circuit carrier 2 and the housing 5 can be dispensed with. The connection element 6 is additionally mechanically stabilized by the fixed connection to the housing 5. The connection element 6 in one embodiment has an elongated and cylindrical form resulting in an axial introduction of the counterforce of the pressure contact 30 into the connection element 6 and complete forwarding of the force to the housing 5. A high mechanical stability of the connection and a high current-carrying capacity required for power semiconductor modules are achieved with the arrangement described.

FIG. 2 illustrates a further example arrangement. A connection element 7 is led out from the housing 5 generally perpendicular to the baseplate 3 and is firmly fixed to the housing 5, such that the connection element 7 is captively connected to the housing 5. A first connection of the connection element 7 is electrically connected to the structure 4, the first connection being formed as a plug contact 40. A sleeve 41 is fixed to the structure 4, the sleeve 41 receiving the plug contact 40. As a result, a more extensive alignment of the connection element 7 to the sleeve 41 for producing the electrical contact between connection element 7 and structure 4 is not necessary during the positioning of the housing 5 with respect to the baseplate 3.

A pressure contact 50 between the second connection of the connection element 7 has a spring 51. On account of the fixed connection of circuit carrier 2, housing 5, the spring 51 generates a force between the circuit carrier 2 and the structure 4 (see the arrow). In this embodiment, the circuit carrier 2 can be connected to the housing 5 using at least one screw connection 18 (or using latching hooks).

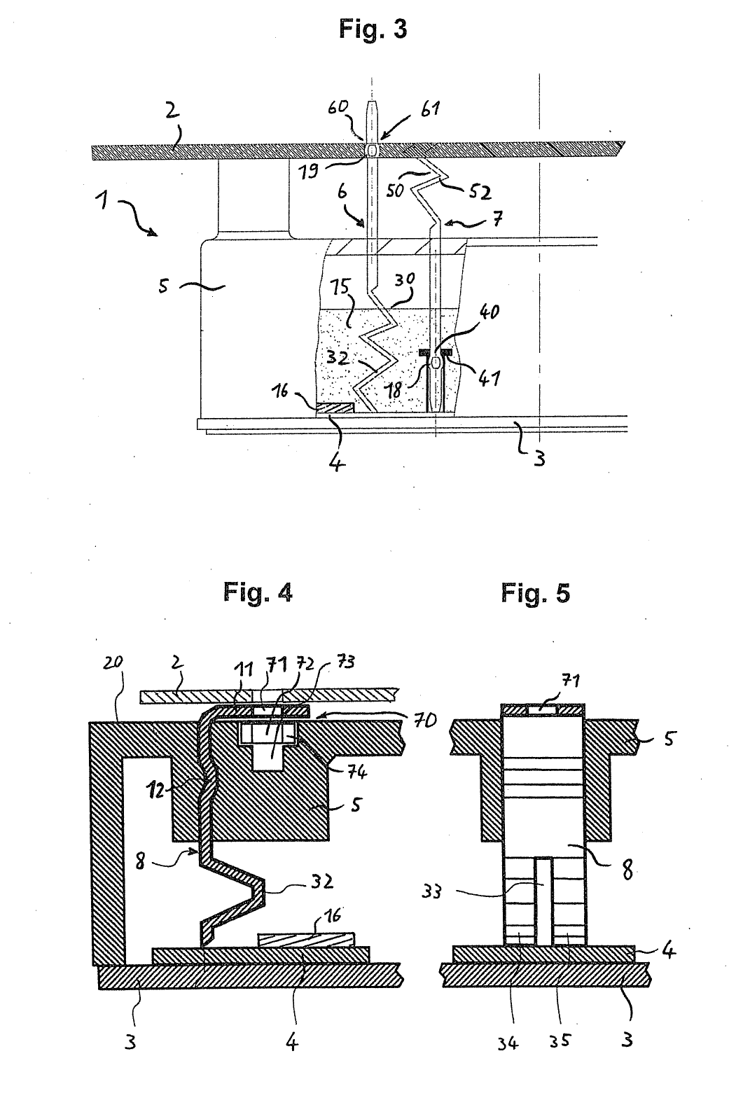

Instead of an independent spring 31 for the pressure contact 30, in the example illustrated in FIG. 3 the connection element 7 itself is provided with a resilient section 32 using a corresponding shaping. Moreover, the plug contact 40 has an elastic widening 18 that is situated within the sleeve 41 in the plugged-in state. The plug connection is effected using the plug contact 60 through an opening 61 in the circuit carrier 2. An elastic widening 19 of the plug contact 60 is situated in the opening 61. The power semiconductor module 1 is potted in the present embodiment, such that pressure contact 30 and plug contact 40 are surrounded by potting compound 15 that serves to protect the power semiconductor components 16 against moisture and dust. The potting compound 15 can be silicone gel, for example.

In one or more embodiments according to FIGS. 4 and 5, the first connection of a connection element 8 is formed by a resilient section 32. Between the pressure contact 30 at the lower end and a screw contact 70 at the upper end of the connection element 8, the latter is injected into the housing 5. In one embodiment, the connection element 8 is curved in a direction parallel to the baseplate 3 in a region 12 that is injection-encapsulated by the housing 5. On account of the curvature, the connection element, on account of the spring effect of the resilient section 32, takes up a counterforce that is greater than for the embodiment where the connection element 8 is injected into the housing 5 without curvature 12. In that region of the connection element 8 which is injection-encapsulated by the housing 5, the curvature 12 in a direction parallel to the baseplate 3 leads to an increased degree of intermeshing with the housing upon taking up a counterforce perpendicular to the baseplate 3. The resilient section 32 can have a cutout 33, whereby at least two resilient sections 34, 35 arise. The sections 34, 35 are illustrated in FIG. 5 in the plan view of the connection element 8 in the mounted state. A plurality of resilient sections open up additional configurational possibilities in the layout of the structure 4.

The second connection of the connection element 8 serves for electrical connection to a circuit carrier 2 and is formed as a screw contact 70. For this purpose, in one embodiment according to FIGS. 4 and 5, the connection element 8, on a side 20 of the housing 5 that is opposite to the baseplate 3 and is remote from the baseplate 3, is bent in a section 11 in a direction parallel to the side 20. The section 11 bears on the side 20 and has a disk-shaped opening 71, which is part of a screw contact 70. For this purpose, the housing 5 has two axially symmetrical cutouts 72 and 73, wherein the cutout 73 has a smaller diameter than the cutout 72 and proceeding from the cutout 72 leads further inward into the housing 5. After the locknut 74 has been introduced into the cutout 72, the disk-shaped opening 71 is arranged coaxially with respect to the cutouts 72, 73. The locknut 74 introduced into the cutout 72 serves as counterpart for screwing a screw (not illustrated) into the opening 71. It suffices, therefore, for the locknut 74 to be fixed loosely in its position using the shaping of the cutout 72 and the section 11 of the connection element 8 that bears on the side 20 of the housing, and in this embodiment to exert a counterforce for the screw. The cutout 73 in the housing 5 finally serves for receiving an end of the screw.

In the embodiment of the screw contact 70 illustrated in FIGS. 4 and 5, the circuit carrier does not have to be connected to the housing 5. The circuit carrier 2 is only connected to the connection element 8 via the opening 71 and the locknut 74. A firm fixing of the connection element 8 in the housing 5 is effected in this embodiment upon coaxial alignment of the disk-shaped opening 71 and the cutouts 72, 73 using the screw. Such a screw contact with a section 11 of the connection element 8 that bears on the housing side 20 and cutouts 72, 73 in the housing 5 permits a compact design of the power semiconductor module. On account of the firm fixing of the connection element 8 in the housing 5, it is possible to dispense with soldering connections between the connection element 8 and the electrically conductive structure 4, on the one hand, and between the connection element 8 and the circuit carrier 2, on the other hand.

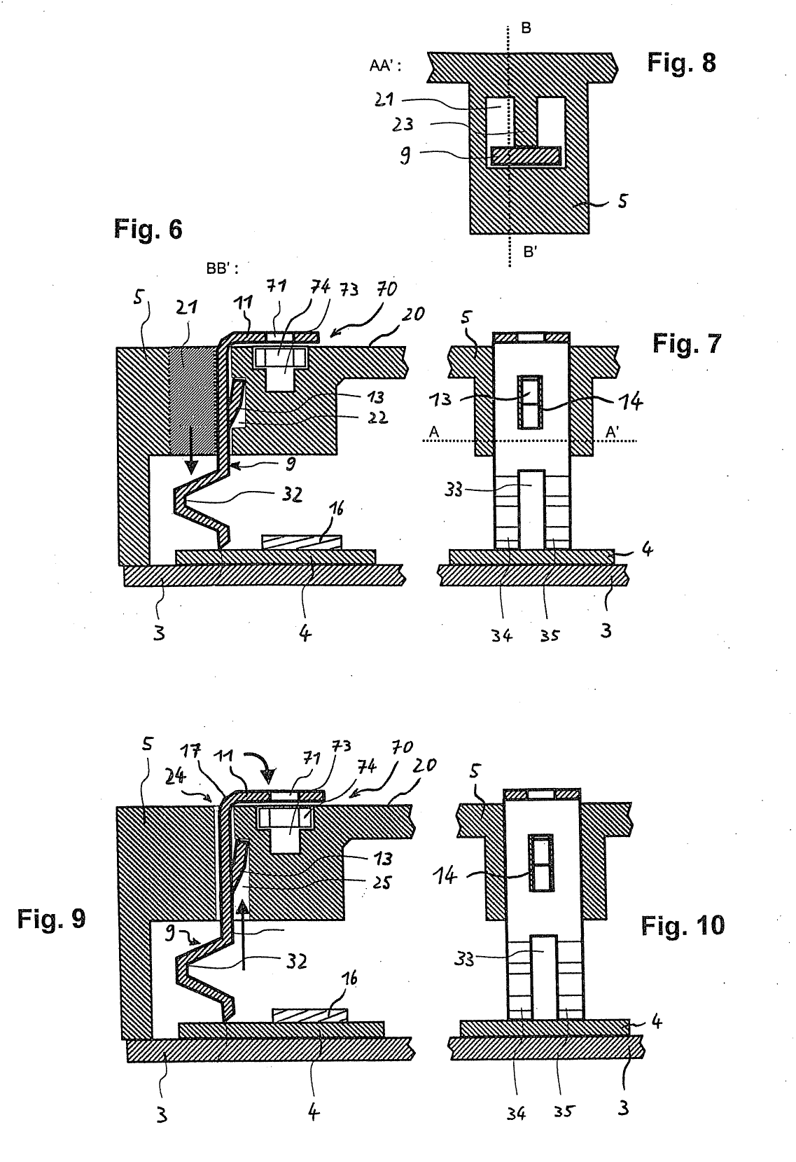

As an alternative to a cohesive connection between connection element and housing, it is also possible to provide a positively locking connection for firmly fixing the connection element. One embodiment is illustrated in FIG. 6, wherein a connection element 9 is inserted into the housing 5 in the direction of the baseplate 3. The housing 5 has an opening 21 with a latching cutout 22. The connection element 9, in addition to being provided with a resilient section 32 as first connection and a screw connection 70 as second connection, is provided with a latching hook 13 between first and second connections.

The latching hook 13 is formed in such a way that it firmly fixes the connection element 9 to the housing with the assistance of the bent section 11 and of the resilient section 32 if the connection element 9 is situated in the opening 21. For its part, the latching hook 13 is formed in resilient fashion, such that the latching hook 13 can latch into a latching cutout 22 in the opening 21. A latching hook 13 can be realized for instance by virtue of the connection element 9 having a U-shaped cutout 14 and the part enclosed by the U-shaped cutout 14 being bent outward, a certain amount of elasticity of the outwardly bent part remaining. When the connection element 9 is inserted, the latching hook 13 is pressed in the direction of the cutout 14. The stress on the latching hook 13 is partially relieved in the latched-in state. As a result of the only partial stress relief of the resilient latching hook 13, the connection element 9 is pressed against the web 23.

FIG. 7 illustrates, in plan view and in the mounted state, the connection element 9 with the cutout 14, the latching hook 13 arranged in the cutout 14, and also the U-shaped configuration of the resilient region 32, which in turn leads to resilient sections 34, 35. In one embodiment illustrated in FIG. 8, the opening 21 in the housing 5 has a web 23 that presses the connection element 9 onto the housing 5 in the latched-in state. This gives rise to cavities into which for example the resilient sections 34, 35 from FIG. 7 can run when the connection element 9 is inserted in the direction of the baseplate 3.

When the housing 5 is potted with a casting compound 15 it is not necessary to close off the cavities that arise as a result of the web 23 in the opening 21. A firm fixing of the connection element 9 to the housing 5 is already achieved by virtue of the fact that the housing prevents a movement of the connection element 8 in a plane spanned by the baseplate 3. In addition, the latching hook 13 prevents a displacement of the connection element 9 away from the baseplate 3. In the direction of the baseplate 3, the section 11 of the screw contact 70 that bears on the housing side 20 prevents a displacement of the connection element 9. The spring effect of the latching hook 13 also contributes to a further fixing.

In addition to the above-described insertion of the connection element into the housing in the direction of the baseplate 3, insertion in the opposite direction is likewise possible. FIG. 9 illustrates one embodiment with the connection element 9 from FIG. 6 in which the connection element is inserted into the housing 5 in a direction away from the baseplate 3. For this purpose, the housing 5 has an opening 24 for receiving the connection element 9. A latching projection 25 is provided into the opening 21 of the housing 5, the latching hook 13 of the connection element 9 latching into the latching projection. The connection element 9 is inserted into the housing 5 with unbent section 11 in a direction away from the baseplate 3. It is only after the connection element 9 has been inserted into the opening 24 that the section 11 is bent over at a location 17 so as to be disposed parallel to the housing side 20.

As illustrated in FIG. 9 and FIG. 10, the latching hook 13 of the connection element 9 can be in the form of a spring that is tensioned in the latched-in state of the connection element 9. A resilient latching hook in the latched-in state is illustrated in plan view in FIG. 10. The resilient latching hook 13, as already illustrated in FIG. 7, is formed by a U-shaped cutout 14, wherein the latching hook 13 is composed of the material of the connection element 9 and is arranged within the cutout 14.

As set out above, therefore, arrangements are proposed in which a connection element of a power semiconductor module is led out from a housing of the power semiconductor module essentially perpendicular to a baseplate and the connection element is firmly fixed to the housing, whereby the connection element is captively connected to the housing. As a result of the firm fixing of the connection element to the housing, it is possible to dispense with soldering the connection element onto an electrically conductive structure of a baseplate or of a circuit carrier. Instead, a first connection of the connection element is in a form of a pressure contact, plug contact, screw contact or the like. Provision is furthermore made for forming a second connection of the connection element as a pressure contact, plug contact, screw contact or the like.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power semiconductor arrangement comprising:
a power semiconductor module comprising a baseplate with an electrically conductive structure, a housing and a connection element;
wherein the connection element is led out from the housing generally perpendicular to the baseplate and is fixed to the housing, including a first connection configured for making contact with the electrically conductive structure, and a second connection configured for making electrical contact with a circuit carrier.

2. The arrangement of claim 1 comprising where the first connection is a pressure contact or plug contact, and the second connection is a pressure contact, plug contact, or screw contact.

3. The arrangement of claim 1, comprising:
wherein the connection element is injected into the housing.

4. A power semiconductor arrangement comprising:
a power semiconductor module and a circuit carrier, wherein the power semiconductor module comprises a baseplate with an electrically conductive structure, a housing and a connection element; and
wherein the connection element is led out from the housing generally perpendicular to the baseplate and is fixed to the housing, including a first connection for making contact with the electrically conductive structure, the first connection being a pressure contact or plug contact, and a second connection for making electrical contact with the circuit carrier, the second connection being a pressure contact, plug contact, or screw contact.

5. The arrangement of claim 4, wherein the connection element comprises a single pressure contact.

6. The arrangement of claim 5, comprising wherein the housing is fixedly connected to the baseplate by screw connection, by adhesive bonding or at least one latching hook.

7. The arrangement of claim 4, comprising wherein the housing is fixedly connected to the circuit carrier by using at least one screw connection or at least one latching hook.

8. The arrangement of claim 4, wherein the connection element comprises copper, brass or steel.

9. The arrangement of claim 4, wherein the connection element comprises an elongated, cylindrical form.

10. The arrangement of claim 4, wherein at least one pressure contact is provided and the pressure contact of the connection element comprises a spring.

11. The arrangement of claim 4, wherein at least one pressure contact is provided, wherein the pressure contact of the connection element is formed in one piece and comprises a springlike section.

12. The arrangement of claim 11, wherein the resilient section of the pressure contact comprises at least one cutout in such a way that it comprises at least two resilient partial sections in the region of the cutout.

13. The arrangement of claim 4, wherein the connection element comprises at least one plug contact, wherein a sleeve for receiving the connection element is fixed on the baseplate.

14. The arrangement of claim 4, comprising wherein the connection element is injected into the housing.

15. The arrangement of claim 14, wherein the connection element comprises a curvature in a region that is injection-encapsulated by the housing.

16. A power semiconductor arrangement comprising:
a power semiconductor module comprises a baseplate with an electrically conductive structure, a housing and a connection element;
wherein the connection element is led out from the housing generally perpendicular to the baseplate and is fixed to the housing, including a first connection configured for making contact with the electrically conductive structure, and a second connection configured for making electrical contact with a circuit carrier; and
wherein the connection element comprises, on a side of the housing that is opposite to the baseplate and remote from the latter, a bent section in a direction parallel to the side of the housing.

17. The arrangement of claim 16, wherein the second connection of the connection element comprises a disk-shaped opening for a screw contact.

18. The arrangement of claim 17, wherein the housing comprises an axially symmetrical cutout for receiving a locknut, wherein the disk-shaped opening is arranged coaxially with respect to the cutout.

19. The arrangement of claim 16, wherein the connection element comprises a latching hook between its first and second connection, the connection element together with the bent section of the connection element being fixed to the housing by using the latching hook.

20. The arrangement of claim 19, wherein the connection element comprises a U-shaped cutout and the latching hook is formed from the outwardly bent part of the connection element that is enclosed by the U-shaped cutout.

21. The arrangement of claim 19, wherein the housing comprises an opening for receiving the connection element, into which opening the connection element is inserted in the direction of the baseplate, wherein a cutout is situated laterally in the opening, the latching hook being latched into the cutout, and wherein the latching hook is formed in resilient fashion and is tensioned in the latched-in state of the connection element.

22. The arrangement of claim 21, wherein the housing comprises a web in the opening, against which web the connection element is pressed in the latched-in state.

23. The arrangement of claims 21, wherein the housing comprises an opening for receiving the connection element, into which opening the connection element is inserted in a direction leading away from the baseplate, and a projection is present in the opening, the latching hook engaging into the projection.

24. A method of making a power semiconductor arrangement comprising:
providing a power semiconductor module comprising a baseplate with an electrically conductive structure, a housing and a connection element, wherein the connection element is led out from the housing generally perpendicular to the baseplate and is fixed to the housing;
making contact with the electrically conductive structure via a first connection; and
making electrical contact with a circuit carrier via a second connection.

25. An arrangement comprising:
a power semiconductor module comprising a baseplate with an electrically conductive structure, a housing and a connection element, wherein the connection element is led out from the housing generally perpendicular to the baseplate and is fixed to the housing;
first connection means for making contact with the electrically conductive structure; and
second connection means for making electrical contact with a circuit carrier.
